(19) United States
(12) Patent Application Publication
(10) Pub. No.: US 2026/0155627 A1
(43) Pub. Date: Jun. 4, 2026

(54) ETCH-FREE OPTICAL METASURFACE SUPPORTING MILLION-QUALITY-FACTOR RESONANCES AT VISIBLE WAVELENGTHS IN FREE SPACE

(71) Applicants: University of Washington, Seattle, WA (US); Research Foundation of The City University of New York, New York, NY (US)

(72) Inventors: Jie Fang, Seattle, WA (US); Arka Majumdar, Seattle, WA (US); Rui Chen, Seattle, WA (US); David Sharp, Seattle, WA (US); Enrico Renzi, New York, NY (US)

(73) Assignees: University of Washington, Seattle, WA (US); Research Foundation of The City University of New York (RFCUNY), New York, NY (US)

(21) Appl. No.: 19/405,884

(22) Filed: Dec. 2, 2025

Related U.S. Application Data
(60) Provisional application No. 63/726,910, filed on Dec. 2, 2024.

(51) Int. Cl. H01S 5/183

(52) U.S. Cl. CPC H01S 5/1835; H01S 5/18369

(57) ABSTRACT

Etch-free optical metasurface (free space optical resonator) supporting million-quality-factor resonances at visible wavelengths in free space and associated systems and methods are described. In an embodiment, a free space optical resonator includes: a low refractive index layer; a high refractive index layer having a wide band gap; and a low refractive index resist layer. The high refractive index layer is disposed between the low refractive index layer and the resist layer. The resist layer includes a 2-D subwavelength periodic pattern of openings. The low refractive index layer, the high refractive index layer and the low refractive index resist layer are arranged as a vertical stack. The optical resonator is lossless at visible wavelengths of light.

### CROSS-REFERENCE TO RELATED APPLICATION

This application claims the benefit of U.S. Application No. 63/726,910, filed on Dec. 2, 2024, the disclosure of which is hereby incorporated by reference in its entirety.

### STATEMENT OF GOVERNMENT LICENSE RIGHTS

This invention was made with government support under Grant No. R01GM146962, awarded by the National Institute of General Medical Sciences (NIGMS) [NIH] and Grant Nos. DMR-2019444 and NNCI-1542101 and NNCI-2025489 and NSF-2103673, awarded by the National Science Foundation (NSF). The government has certain rights in the invention.

### BACKGROUND

High-quality (Q)-factor optical resonators with extreme temporal coherence are of both technological and fundamental importance in optical metrology, continuous-wave lasing, and semiconductor quantum optics. Despite extensive efforts in designing high-Q resonators across different spectral regimes, the experimental realization of very large Q-factors at visible wavelengths remains challenging due to the small feature size that is sensitive to fabrication imperfections, and thus is typically implemented in integrated photonics. Accordingly, improved high-quality (Q)-factor optical resonators in free space and associated methods are still needed.

### SUMMARY

This summary is provided to introduce a selection of concepts in a simplified form that are further described below in the Detailed Description. This summary is not intended to identify key features of the claimed subject matter.

In the pursuit of free-space optics with the benefits of large space-bandwidth product and massive parallel operations, the inventors design and fabricate an etch-free metasurface with minimized fabrication defects and experimentally demonstrate a million-scale ultrahigh-Q resonance at visible and near-infrared wavelengths. In the context of this specification, the terms metasurface and optical resonator are used interchangeably. The term free space optical resonator means that the device functional area is exposed to free space and the incident and modulated light signals both propagate in free space, e.g., ambient air.

Inventors have developed a laser-scanning momentum-space-resolved spectroscopy technique with extremely high spectral and angular resolution to characterize the record-high Q-factor as well as the dispersion of the million-Q resonance in free space. By integrating an active light emitting layer (e.g., a monolayer WSe₂) into the inventive ultrahigh-Q optical resonator, the inventors further demonstrate laser-like highly unidirectional and narrow-linewidth exciton emission, albeit without any operating power density threshold. Under continuous-wave laser pumping, pump-power-dependent linewidth narrowing at room temperature is observed, indicating the potential of the inventive meta-optics platform in controlling coherent quantum light-sources. Obtained results also holds significant promise for applications like optical sensing, spectral filtering, and few-photon nonlinear optics.

High-quality (Q)-factor optical resonators with ultranarrow spectral linewidth (Γ_{ω}=ω₀/Q, where ω₀ is the resonance frequency) play a crucial role in modern photonics and quantum optics, facilitating extreme temporal coherence, with lifetime on the time scale of ˜Q/ω₀. Numerous essential applications, including optical frequency combs, monochromatic lasers, low-photon-number nonlinear optics, unidirectional nano-emitters, and cavity quantum electrodynamics studies, significantly depend on high-Q resonators. This has led to extensive efforts in designing ultrahigh-Q resonators across different spectral regimes. However, experimentally realizing very large Q-factors at shorter wavelengths, e.g., visible wavelengths, remains an outstanding challenge due to material and fabrication constraints. The primary difficulty lies in fabrication imperfections that cause unwanted scattering loss and deviations from the intended design, which are much more severe in visible-wavelength devices, because their small feature sizes are on a similar scale as the fabrication defects themselves.

At visible and near-infrared wavelengths, million-scale (10⁶) Q-factors have been accessed in individual photonic resonators such as evanescently-coupled micro-ring and micro-disk cavities, and free-space-coupled microtoroids. Due to tight spatial confinement of light, one can minimize the defect-sensitive area in these resonators. In contrast, free-space lattice-resonant implementations such as metasurfaces and photonic crystal slabs have larger functional areas (which enable large space-bandwidth product), and thus are highly defect-sensitive and face additional challenges, including long-range non-uniformity, substrate-induced out-of-plane asymmetry, and modal dispersion. Experimentally reported Q-factors in the conventional free-space resonators typically fall within a scale of only 10³ (see Table 1 below) in the visible regime.

Despite these challenges, there is an outstanding and ever-growing demand for ultrahigh-Q free-space optics due to their distinct advantages of large space-bandwidth product, easy free-space access, and parallel signal/data operations. These unmet needs resulted in topological metasurfaces (optical resonators) that are meticulously engineered to be more resilient to fabrication defects, for instance, by merging multiple bound states in the continuum (BICs) in momentum space. However, in these approaches, the substrate needs to be removed to minimize out-of-plane asymmetry and the lack of lossless high-index materials at visible wavelengths may also limit design feasibility. Moreover, despite the improvements, the experimental Q-factors still fall short by orders of magnitude compared to those in integrated-optics resonators.

The inventive technology presents a design and experimentally demonstrates a million-scale ultrahigh-Q guided mode resonance (GMR) at visible and near-infrared wavelengths in a resist-based etch-free metasurface (e.g., as shown in FIGS. 1A and 1B below). Etching is a process that patterns the materials but also introduces undesirable roughness and defects in the structures that are patterned. An ‘etch-free’ design procedure aims to minimize fabrication imperfections, rather than to engineer the device's robustness to imperfections. The inventive technology adapts the etch-free metasurface (optical resonator) strategies under the material constraints of visible regime, and advances visible-wavelength free space meta-optics toward a million-Q performance.

To characterize a million-Q resonance under free-space visible wavelength excitations, inventors developed a new laser-scanning momentum-space-resolved spectroscopy technique that combines a tunable-wavelength laser and a momentum-space imaging system to visualize the modal dispersion in the full energy-momentum space with ultrahigh resolution in wavelength (˜0.42 pm) and angle (˜0.028°).

The inventive technology can be readily used in various applications including optical sensing, filtering, quantum light sources, and few-photon nonlinear optics. As an example, the inventors integrate monolayer WSe₂ into the ultrahigh-Q optical resonator and demonstrate highly unidirectional and narrow-linewidth exciton emission. The ultrahigh-Q cavity effectively boosts the density of states at the Γ point, and a pump-power-dependent emission concentration towards the Γ point under continuous-wave (CW) laser pumping is observed at room temperature.

With the inventive technology, only the light wavelengths of the design choice are modulated by the optical resonator. In many embodiments, the primary design choices are a distance between openings (pitch or P) and size of the opening itself (characteristic dimension or L). Design choice is also affected by the choice of materials and thicknesses of each layers. These design features are generally realized on a semiconductor scale (a nm scale), which is also the scale of visible light wavelength.

In one embodiment, a free space optical resonator includes: a low refractive index layer; a high refractive index layer having a wide band gap; and a low refractive index resist layer. The high refractive index layer is disposed between the low refractive index layer and the resist layer. The resist layer includes a 2-D subwavelength periodic pattern of openings. The layers are arranged as a vertical stack. The optical resonator is lossless at visible wavelengths of light.

In one embodiment, a method of manufacturing a free space optical resonator includes: disposing a low refractive index layer; disposing a high refractive index layer having a wide band gap over the low refractive index layer; disposing a low refractive index resist layer over the high refractive index layer; and etch-free patterning the resist layer into a 2-D subwavelength periodic pattern of openings. The optical resonator is lossless at visible wavelengths of light.

### DESCRIPTION OF THE DRAWINGS

The patent or application file contains at least one drawing/photograph executed in color. Copies of this patent or patent application publication with color drawing(s) will be provided by the Office upon request and payment of the necessary fee.

The foregoing aspects and many of the attendant advantages of this invention will become more readily appreciated as the same become better understood by reference to the following detailed description, when taken in conjunction with the accompanying drawings, where:

FIGS. 1A and 1B are isometric views of free space optical resonators in accordance with embodiments of the present technology.

FIG. 2 is a top view of a free space optical resonator in accordance with embodiments of the present technology;

FIG. 3 is a flow chart of a method of manufacturing of a free space optical resonator in accordance with embodiments of the present technology;

FIG. 4 is a side view of free space optical resonator in accordance with embodiments of the present technology;

FIG. 5 is a graph of wavelengths vs. guided mode effective index (dispersion relationship) for an unpatterned device, used for designing the value of P in the patterning, in accordance with an embodiment of the present technology;

FIG. 6 is a graph of a quality factor vs. the value of L for a device in accordance with an embodiment of the present technology;

FIGS. 7A-7C illustrate several graphs of reflectance signals at different wavelengths and light signal angles with respect to device surface normal in accordance with embodiments of the present technology;

FIG. 8 illustrates a measurement system in accordance with embodiments of the present technology; and

FIGS. 9A-9C show several graphs of reflectance signals at different wavelengths and light signal angles with respect to device surface normal in accordance with embodiments of the present technology;

FIGS. 10A-10C show several graphs of normalized reflectance vs. photon energy (light wavelength) in accordance with embodiments of the present technology; and

FIG. 10D shows experimental results of reflectance signals at different wavelengths and light signal angles with respect to device surface normal in accordance with embodiments of the present technology.

### DETAILED DESCRIPTION

While several embodiments have been illustrated and described, it will be appreciated that various changes can be made therein without departing from the spirit and scope of the claimed subject matter. Example devices, methods, and systems are described herein. It should be understood the words “example,” “exemplary,” and “illustrative” are used herein to mean “serving as an example, instance, or illustration.” Any embodiment or feature described herein as being an “example,” being “exemplary,” or being “illustrative” is not necessarily to be construed as preferred or advantageous over other embodiments or features. The example embodiments described herein are not meant to be limiting. It will be readily understood aspects of the present disclosure, as generally described herein, and illustrated in the figures, can be arranged, substituted, combined, separated, and designed in a wide variety of different configurations, all of which are explicitly contemplated herein.

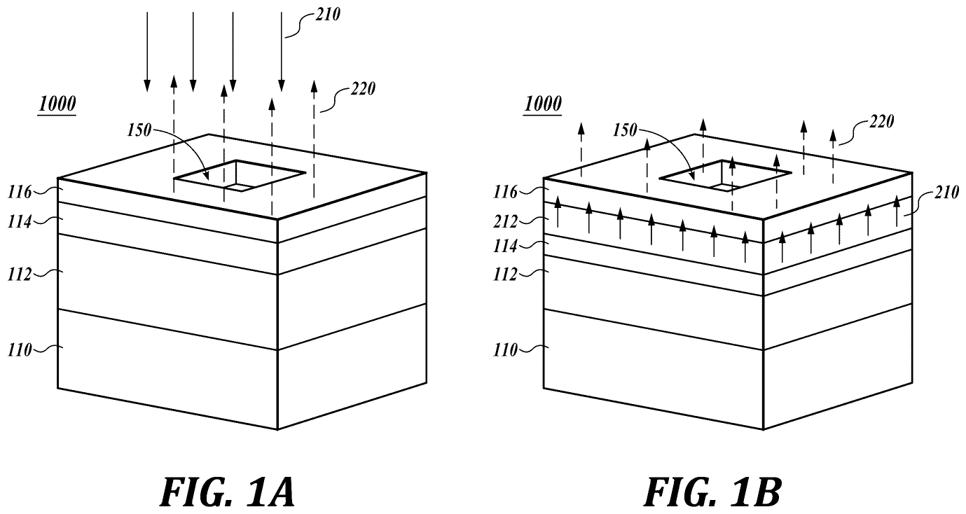

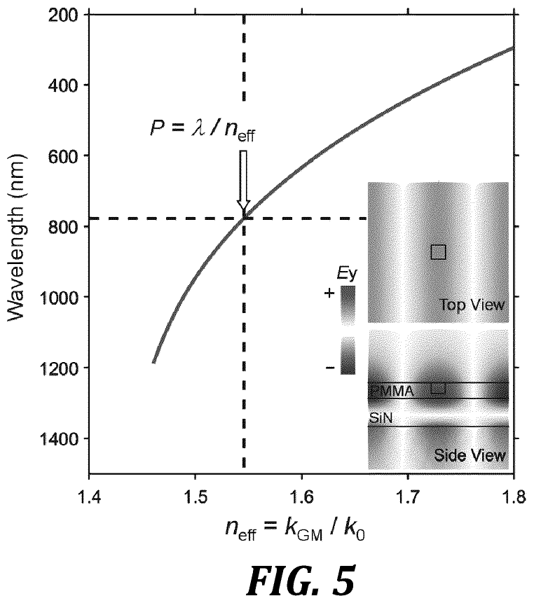

FIGS. 1A and 1B are isometric views of free space optical resonators in accordance with embodiments of the present technology. FIG. 1A illustrates a unit cell of the etch-free metasurface 1000. In practice, the optical resonator 1000 includes a 2D array of optical resonator, possibly having hundreds or thousands such unit cells. Such arrangement of multiple unit cells is further discussed with respect to FIG. 5 below. The metasurface 1000 may operate as a free space optical resonator, hence the terms ‘metasurface’ and “optical resonator” are used interchangeably in this specification.

The unit cell optical resonator 1000 includes, from top to bottom, a patterned resist layer 116, a high refractive index layer 114, and a low refractive index layer 112. In some embodiments, unit cell optical resonator 1000 also includes a substrate layer (a carrier) 110. In some embodiments, the patterned resist layer 116 may be a polymethyl methacrylate (PMMA), a transparent thermoplastic polymer commonly known by trade names like Plexiglass, Acrylite, Lucite, or simply acrylic glass. The patterned resist layer 116 may be about 58-nm-thick PMMA layer. In some embodiments, the high refractive index layer 114 is a SiN layer, that may be 100-nm-thick. In some embodiments, the low refractive index layer 112 is an SiO₂ layer that may be about 1470-nm thick. In general, different thicknesses are possible in different embodiments, the above-listed example thicknesses being suitable for being made by semiconductor manufacturing equipment. The substrate layer 110 may be an Si substrate, for example, a blank Si wafer. The patterning is defined by the period P and defect hole size L, as further described below. Sample values of refractive index for the materials of a low refractive index layer are from 1 to 1.7. Sample values of refractive index for the materials of a high refractive index layer having a wide band gap are above 1.7.

The illustrated stack supports both transverse electric (TE) and transverse magnetic (TM) guided modes with different cut-off wavelengths. The cut-off wavelengths are defined primarily by the materials and thicknesses of each layer. A direction of the incoming light is marked by arrows 210, and a direction of the outgoing light, after being processed by the optical resonator 1000, is marked by arrows 220. The incoming light 210 may be produced by an external laser or light emitting diodes (LEDs).

In some embodiments, the optical resonator is considered lossless at visible wavelengths of light. The term “lossless” refers to a very small amount of light absorbed by the device (not including substrate), for example, losses below 5% of total incident energy.

FIG. 1B illustrates unit cell of another etch-free optical resonator 1000. The illustrated optical resonator 1000 is similar to that of FIG. 1A, except that the optical resonator of FIG. 1B includes a light emitting semiconductor layer 212 (also referred to an active light emitting layer 212), which may be, for example, a layer of LEDs, photodiodes or other optically active material that, when energized, emits the incoming light 210. In some embodiments, the active light emitting layer 212 is configured to generate light that matches with characteristic wavelengths of operation of the free space optical resonator. In operation, the optical resonator 1000 produces the outgoing light 220 based on the incoming light 210 produced by the active light emitting layer 212.

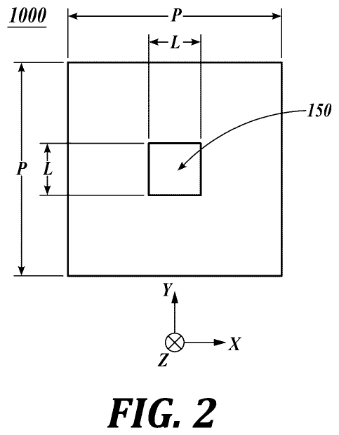

FIG. 2 is a top view of a free space optical resonator in accordance with embodiments of the present technology. More precise, a single unit cell of the optical resonator 1000 is illustrated, whereas a practical optical resonator 1000 includes a 2D array of cells, possibly numbering hundreds or thousands of unit cells in the X-Y plane. As explained above, the operation wavelengths are defined primarily by the period (pitch) P, but also by defect hole size L and other geometrical and optical parameters of the layers of the optical resonator 1000. In some embodiments, the patterning period P of the openings is within a range of 480 nm to 500 nm. In some embodiments, characteristic dimension L (the ‘length’ of the opening) is within a range of 50 nm to 90 nm.

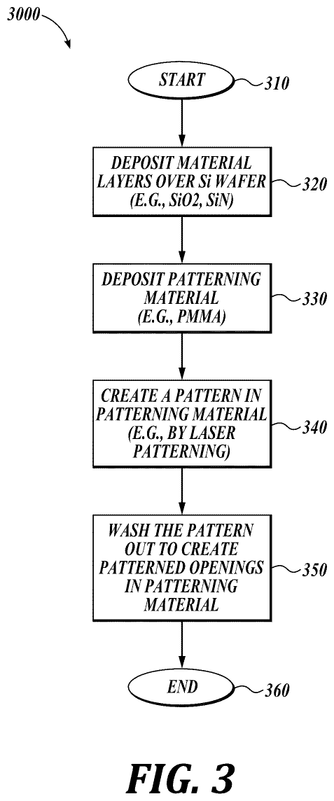

FIG. 3 is a flow chart of a method of manufacturing of a free space optical resonator in accordance with embodiments of the present technology. In different embodiments, the method may be practiced with less steps than is illustrated, or with additional steps that are not illustrated.

The method 3000 starts in block 310. In block 320, material layers are deposited over a substrate using semiconductor manufacturing equipment. In some embodiments, the deposited layers may be SiO₂ as an example of a low refractive index layer 112 and SiN as an example of high refractive index layer 114. Other suitable semiconductor materials can be used in different embodiments. In some embodiments, a light emitting semiconductor layer 212 can be deposited by using, for example, multiple semiconductor manufacturing steps that are not described in detail here. Such light emitting semiconductor layer 212 may serve as a source of light in some embodiments. In some embodiments, the layers of the optical resonator are fabricated on a 1470-nm-thick SiO₂ on silicon substrate (UniversityWafer, Inc.). The device for integration of active light emitting semiconductor layer (e.g., WSe₂ layer) may be fabricated on a JGS1 fused silica substrate (UniversityWafer, Inc.). A 100-nm-thick layer of Si₃N₄ may be grown on top of the substrates through low-pressure chemical vapor deposition (LPCVD) by UniversityWafer, Inc.

The wafer can be diced into 8×8 mm² chips (DAD321, Disco America). Next, the chips are thoroughly cleaned by sonication in acetone, followed by isopropyl alcohol (IPA), each for 5 minutes. After that, the SiN surface is treated by oxygen plasma at 150 W for 5 minutes to dry the surface and remove any solvent residue (AutoGlow, Glow Research).

In block 330, a low refractive index resist material is disposed over the high refractive index layer 114 or over the light emitting semiconductor layer 212. In some embodiments, the resist material may be a layer of polymethyl methacrylate (PMMA). In some embodiments, a 58-nm-thick layer of positive-tone resist PMMA is spin-coated and annealed under 180° C. for 3 minutes.

In block 340, a pattern is created in the resist material. In some embodiments, such pattern is created by an electron-beam lithography at a semiconductor scale, e.g., at a nm scale. A layer of conductive polymer (DisCharge H₂O) is spin-coated on top of the resist layer before the exposure to electron beam. A person of ordinary skill would know that exposing some areas of the resist material to the electron-beam lithography, while not exposing other areas, can make the exposed areas behave differently than the unexposed ones, as described below with respect to block 350.

In block 350, the exposed pattern is washed out using solvents (e.g., water), which creates openings 150. Such openings may be arranged in a 2D pattern for each optical resonator 1000 that is manufactured over the wafer (in general, a given wafer will include a plurality of optical resonators 1000, depending on the diameter of the wafer and size of the optical resonator). The openings 150 are characterized by relatively smooth and precise walls, because no conventional etching is used in creating the openings 150. In some embodiments, the pattern of openings is defined using a JEOLJBX-6300FS 100 kV electron-beam lithography system, followed by development in a cold water/IPA mixture for 2 minutes.

Because the openings 150 are made without the etching process, the optical resonator 100 is referred to as an etch-free optical resonator. A person of ordinary skill would know that etching tends to create imperfections in the opening. Such imperfections are difficult to control and are generally undesirable, because the imperfections create sources of errors and losses for the operation of the optical resonator 1000. The illustrated method ends in block 360.

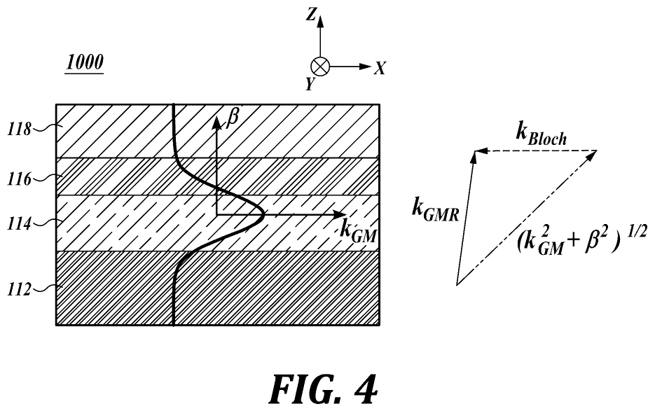

FIG. 4 is a side view of the free space optical resonator 1000 in accordance with embodiments of the present technology. The illustrated metasurface configuration and a possible design flow from a nonradiative guided mode to a radiative ultrahigh-Q GMR described as follows. Turning attention to the four-layer slab waveguide in FIG. 4, the waveguide (also referred to as the optical resonator) includes, from top to bottom, a semi-infinite environment (e.g., air) superstrate 118 (hence the term ‘free space’ optical resonator), a resist layer 116 (e.g., a 58-nm-thick layer of polymethyl methacrylate (PMMA)), a high refractive index layer 114 (e.g., a 100-nm-thick layer of SiN), and a low refractive index layer 112 (e.g., a semi-infinite SiO₂ substrate). The resist layer 116 includes openings 116 (not shown in FIG. 4). This stack (an optical resonator) supports both transverse electric (TE) and transverse magnetic (TM) guided modes with different cut-off wavelengths. For simplicity, we can focus on the wavelengths where only the fundamental TE modes exist, for which the electric field is E(x,z)=ŷE_{y}(z)e^{ik}^{_{GM}}^{x}. k_{GM} is the propagation constant (i.e., in-plane component of the guided mode wave vector), which can be found by solving the transcendental dispersion equation,

$$tan {β}_{3} {h}_{SiN} = \frac{{β}_{3} ( {κ}_{1} {κ}_{4} - {β}_{2}^{2} ) tan ( {β}_{2} {h}_{PMMA} ) + {β}_{3} {β}_{2} ( {κ}_{1} + {κ}_{4} )}{( {β}_{3}^{2} {κ}_{1} + {β}_{2}^{2} {κ}_{4} ) tan ( {β}_{2} {h}_{PMMA} ) + {β}_{2} ( {β}_{3}^{2} - {κ}_{1} {κ}_{4} )} . \qquad ( 1 )$$

In this equation,

$${β}_{2} = {[ {n}_{PMMA}^{2} {k}_{0}^{2} - {k}_{GM}^{2} ]}^{1 / 2} and {β}_{3} = {[ {n}_{SiN}^{2} {k}_{0}^{2} - {k}_{GM}^{2} ]}^{1 / 2}$$

are the out-of-plane wave vector components in the PMMA and SiN layers, respectively, where k₀=2π/λ;

$${κ}_{1} = {[ {k}_{GM}^{2} - {n}_{air}^{2} {k}_{0}^{2} ]}^{1 / 2} , and {κ}_{4} = {[ {k}_{GM}^{2} - {n}_{{SiO}_{2}}^{2} {k}_{0}^{2} ]}^{1 / 2}$$

are the decay constants in air and SiO₂, respectively. The symbols n and h represent the refractive indices and thicknesses of different media. The plot in FIG. 5 shows the dispersion of the effective index n_{eff}=k_{GM}/k₀ of the TE₁ mode obtained by solving Eq. (1). Without being bound by theory, it is believed that a very thin PMMA plays an important role here, and the optical near field is expected to be effectively trapped in both the SiN layer (high refractive index layer 114) and PMMA layer (resist layer 112).

By creating a square periodic array of perturbations in the PMMA layer by virtue of a periodic array of openings 150, a structure-induced Bloch momentum k_{Bloch}=2π/P is introduced to compensate for k_{GM} and thereby open a radiative leaky channel for the infinite-Q guided mode to couple into free space. This same notion as expressed in a wave vector analysis sketch is presented to the right of the optical resonator 1000.

FIG. 5 is a graph of wavelengths vs. guided mode effective index (dispersion relationship) for an unpatterned device, used for designing the value of P in the patterning, in accordance with an embodiment of the present technology. The horizontal axis represents guided mode effective index n_{eff} and the vertical axis represents wavelength of light in nm. The dashed black lines show an example of designing a Γ-point resonance at 779 nm. The insets are the corresponding 779 nm GMR mode profiles when P=500 nm and L=50 nm.

A wave vector analysis sketch shown in FIG. 4 above leads to a GMR with wave vector k_{GMR}, whose resonance wavelength is determined by the period of perturbation P and the guided mode dispersion shown in FIG. 5. For instance, to design a Γ-point (normal-incidence) GMR at a given wavelength λ, we need a k_{GMR} with zero in-plane component,

$${n}_{eff} \cdot \frac{2 π}{λ} - \frac{2 π}{P} = 0.$$

The dashed lines in the dispersion plot give an example of determining the value of P for a resonance at 779 nm. Moreover, with a fixed P, we can use the guided mode dispersion curve to predict the GMR dispersion.

The inset in FIG. 5 shows the simulated mode profiles of a 779 nm resonance at the Γ point when P=500 nm and the opening size L=50 nm. From the side view, the resonant near field is clearly trapped at the interface of SiN and PMMA, as predicted by the four-layer model. This feature can guide the design strategy to optimize the field overlap with the integrated functional materials (e.g., light-emitting semiconductor 212).

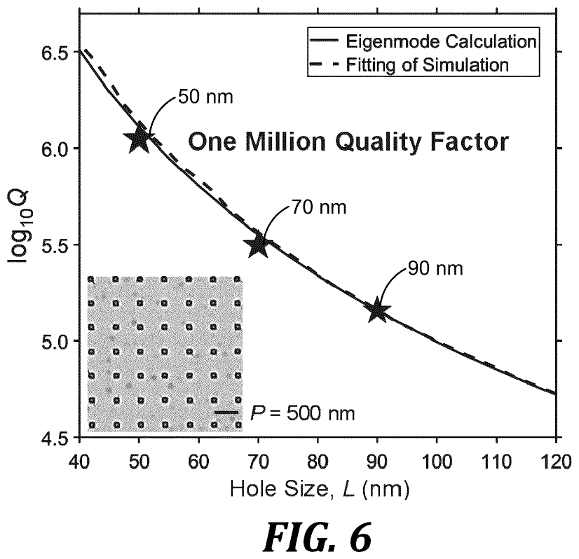

FIG. 6 is a graph of a quality factor vs. the value of L for a device in accordance with an embodiment of the present technology. Similar to a quasi-BIC leaky mode, the extent of periodic perturbations (distance between the openings 150) applied on a photonic bound state (nonradiative guided mode) determines the Q-factor and radiative amplitude of the leaky mode (GMR). In the illustrated metasurface optical resonator, a smaller L induces a larger Q-factor. The predicted Q-factors are obtained through eigenmode simulations (solid line) and Fano fitting of simulated reflection data (dashed line). The close agreement between these methods validates the fitting approach, which is then applied to all experimental spectra.

Three metasurfaces (optical resonators) with fixed P 500 nm and varying L (90, 70, 50 nm) are fabricated and characterized. Note that, to ease the fabrication without affecting the design, the samples may be fabricated on 1470-nm-SiO₂-on-Si wafers as illustrated and described above. The Q-factors of these three devices (corresponding to stars in FIG. 6) all show excellent agreement with theoretical expectation, yielding a record-high Q of a million scale. Such good quantitative agreement stems at least in part from the reduced amount of fabrication imperfection enabled by the etch-free design described in conjunction with FIG. 3, where only the PMMA layer is patterned by electron-beam lithography and a development process, eliminating the need for etching.

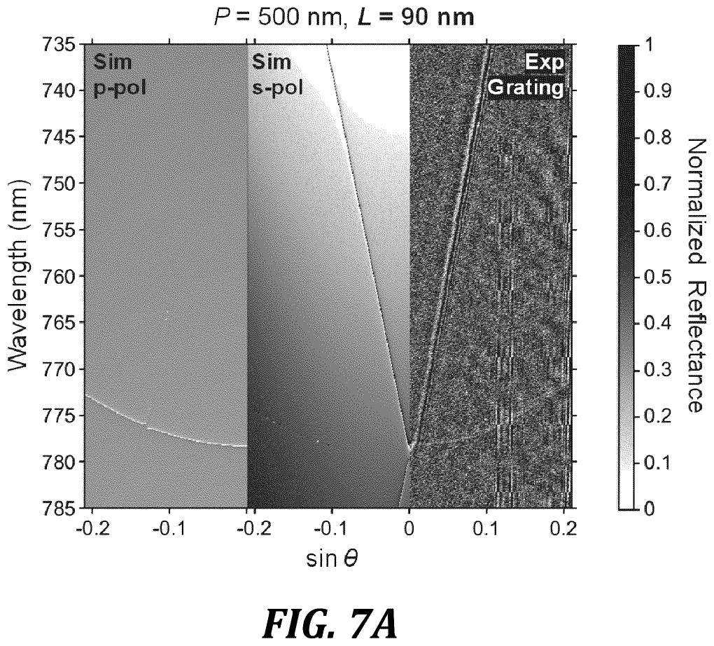

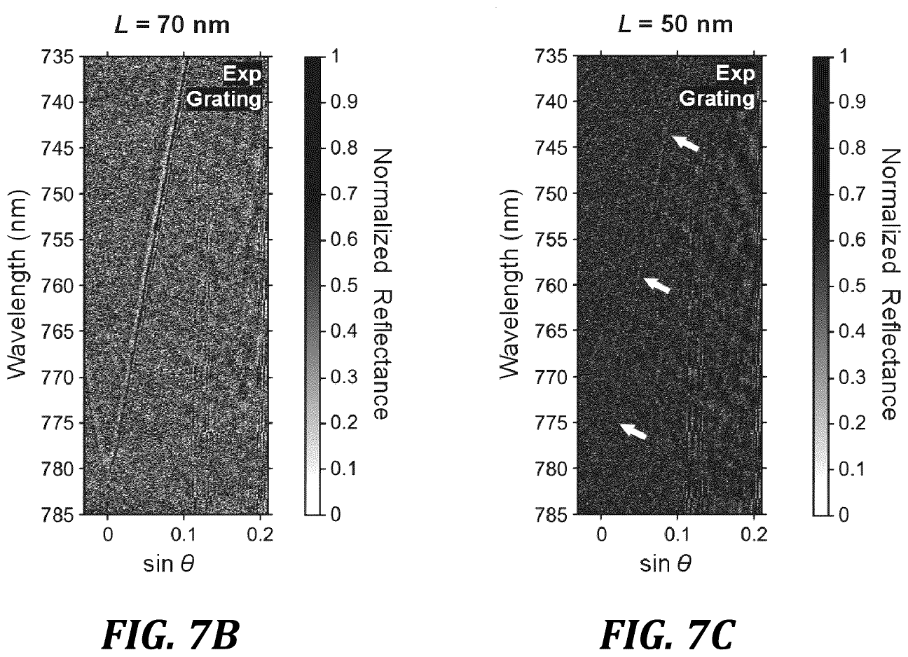

FIGS. 7A-7C illustrate several graphs of reflectance signals at different wavelengths and light signal angles with respect to device surface normal in accordance with embodiments of the present technology. In particular, simulated and experimentally measured momentum-space-resolved reflectance spectra of the sample optical resonators are shown. Angle θ represents angle of the modulated light with respect to device surface normal. With a fixed P of 500 nm, devices with different L are shown: L=90 nm in FIG. 7A, L=70 nm in FIG. 7B, and L=50 nm in FIG. 7C. A spectrometer with a 1200-lines/mm grating is used to differentiate the wavelengths in the spectra. The arrows in FIG. 7C guide the observer towards the GMR feature of interest that is vague due to the ultranarrow linewidth beyond the wavelength resolution. A difference operation is performed, subtracting the background (at unpatterned-PMMA areas) signals from the device signals, to eliminate the multilayer interference influence. The spectra are normalized to their respective maxima.

In many embodiments, random device defects, environmental noise, light path misalignment, or even dust on optical components can cause ‘ghost’ narrow-linewidth spectral features in visible-wavelength free-space measurements. When the linewidth of the studied resonance mode is comparable to these high-frequency background signals, experimental spectral analysis becomes less convincing. To properly characterize an ultrahigh-Q meta-resonator, one needs momentum-space-resolved spectroscopy that enables the visualization of the complete modal dispersions, thereby distinguishing the real resonances from various noise sources. Here, we start with a conventional energy-momentum reflectance spectroscopy that uses a white light source and a grating. As shown in FIGS. 7A-7C, the measured dispersion of all three experimental devices matches well with the simulated GMR response in FIG. 7A, confirming the GMR nature of the measured high-Q modes and again proving high performance of the inventive etch-free optical resonator. FIG. 7A also reveals a co-existence of different resonance modes with s- or p-polarization. A full eigenmode analysis is not shown here, as we focus on the s-polarized ultrahigh-Q GMR with a clean linear dispersion, as highlighted by the arrows in FIG. 7C.

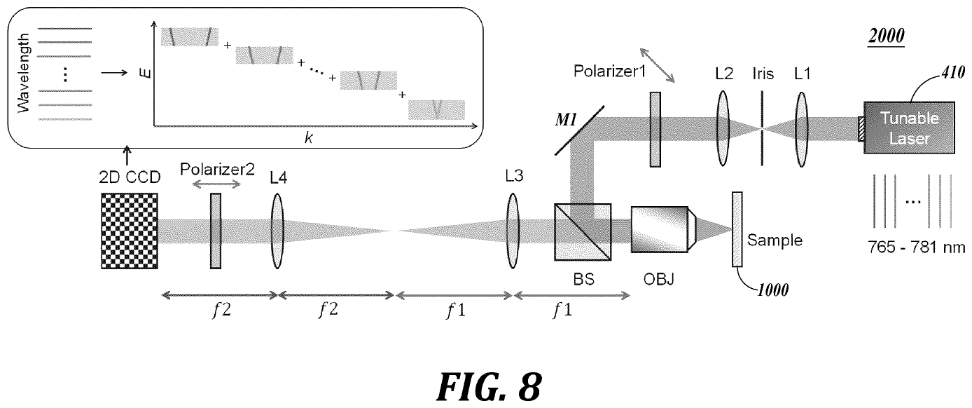

As the Q-factor increases with decreasing L (from FIG. 7A to FIG. 7C), the ultrahigh-Q GMR dispersion curve becomes faint. This suggests that the linewidth of the studied resonance mode is much smaller than the wavelength resolution (˜0.05 nm) of the 1200-lines/mm grating in the setup. Since interference-induced high-Q resonances typically manifest as an asymmetric Fano shape with one peak and one dip, insufficient wavelength resolution can average out the peak and dip, causing incorrect or missing spectral information. This phenomenon is further discussed with respect to FIG. 8 below.

FIG. 8 illustrates a measurement system in accordance with embodiments of the present technology. To characterize a million-Q resonance under free-space visible wavelength excitations, the inventors developed a new laser-scanning momentum-space-resolved spectroscopy technique. The illustrated measurement system combines a tunable-wavelength laser 410 and a momentum-space imaging system to visualize the modal dispersion in the full energy-momentum space with ultrahigh resolution in wavelength (˜0.42 pm) and angle (˜0.028°). Analogous to integrated photonic resonator measurements, the tunable laser 410 is employed to scan the wavelength with extremely high resolution.

Distinctively, the wavelength-scanning laser 410 is integrated into a 4-f momentum-space imaging system, and a two-dimensional charge-coupled device (2D CCD) continuously captures the iso-frequency contours of the photonic band structures at different wavelengths determined by the tunable laser. Illustrated imaging system 2000 includes an arrangement of lenses (L1, L2, L3, L4, OBJ), mirrors (M1), polarizers (Polarizers 1 and 2), CCD camera (2D CCD), beam splitters (BS), irises (Iris), etc. However, a person of ordinary skill would know that analogous arrangements of these components may also be used in different embodiments. The optical resonator 1000 is marked as a “sample” in the context of the imaging system 2000.

In some embodiments light is introduced into the setup via a single-mode fiber. For example, the tunable laser (Newport TLB-6712), continuous-wave pump (Laserglow Technologies 532 nm DPSS Laser), and pulsed pump (NKT SuperK FIU-15 Laser, 78 MHz repetition rate, with a SuperK SELECT tunable multi-channel filter) are all coupled in this manner. The light is first focused on a 75 μm iris using L1 (focal length, f=60 mm) and L2 (f=75 mm) to ensure a uniform Gaussian beam. An objective lens is used to both focus the light onto the sample and collect the reflection/PL signals. To obtain the momentum-space-resolved spectrum, a telescope consisting of lenses L3 (f=180 mm) and L4 (f=150 mm) is employed. Here, L3 and L4 are confocal, L3 is in focus with the back focal plane of the objective lens, and L4 is in focus with the spectrometer CCD (Princeton Instruments Isoplane 160 with PIXIS 400). Insets on top of the left of FIG. 8 highlight the numbers of pixels summed along X axis on CCD when evaluating the momentum-dependent spectral response along Y axis.

In the laser-scanning momentum-space-resolved reflectance measurements, a 2× Mitutoyo Plan Apo Infinity Corrected Long WD Objective (numerical aperture, NA 0.055) is used. To improve the signal-to-noise ratio, a crossed-polarization measurement method is employed by inserting two linear polarizers into the excitation and collection light paths, respectively, as shown in FIG. 8. The second polarizer also determines the polarization of the GMR modes. Note that there is no mirror between Polarizer1 and BS in the actual setup, and a plate beamsplitter is used instead of a cube beamsplitter to avoid extra interference caused by reflections at the optical interfaces.

For signal collection, we use the 2D CCD in the commercial spectrometer with the grating disabled. In some embodiments, the wavelength scanning of the tunable laser and the data capture by the CCD are synchronized and controlled by a Python script.

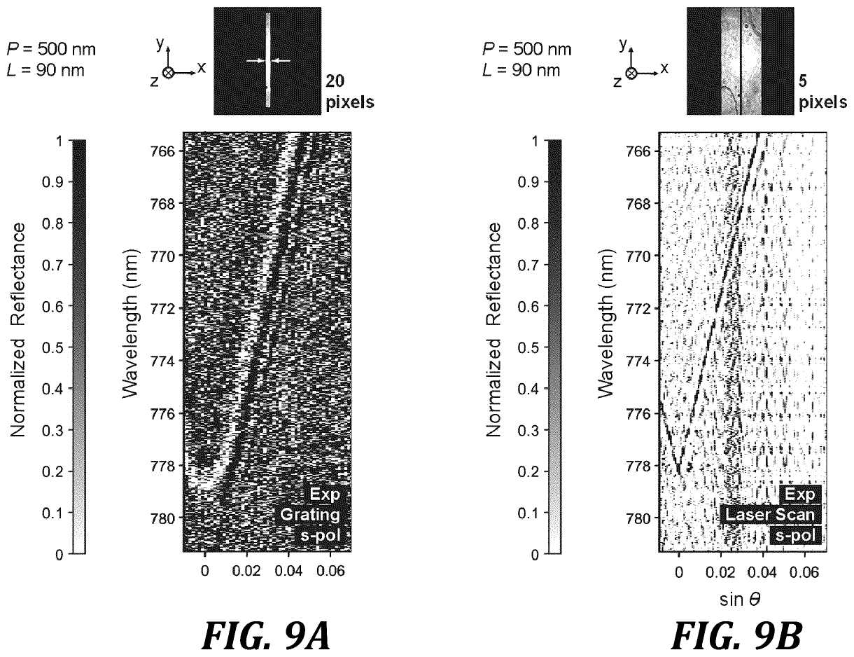

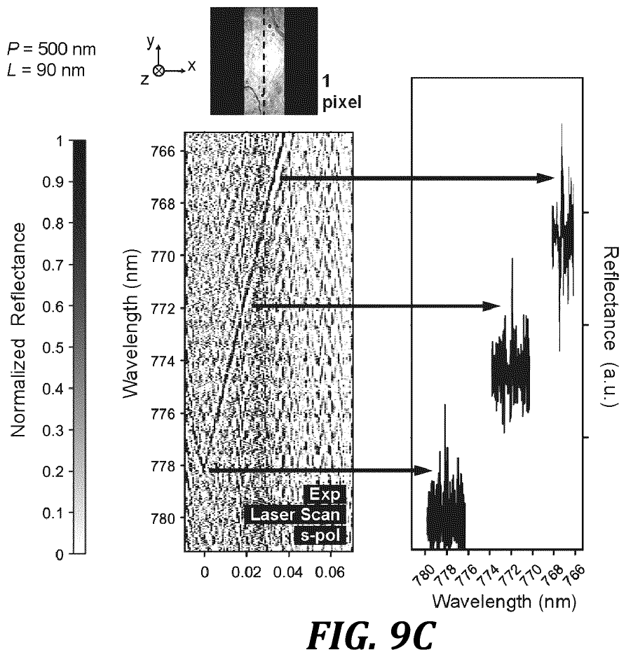

FIGS. 9A-9C show several graphs of reflectance signals at different wavelengths and light signal angles with respect to device surface normal in accordance with embodiments of the present technology. Spectra of the device with P=500 nm and L=90 nm are presented as an example. A spectrometer with a 1200-lines/mm grating provides a wavelength resolution of ˜0.05 nm/pixel in FIG. 9A, while a resolution of ˜2.1 pm/pixel is achieved in FIGS. 9B and 9C via a tunable laser. The angle resolution is ˜0.076°/pixel in 9A with a 10× objective, and ˜0.044°/pixel in FIGS. 9B and 9C with a 2× objective. Insets on top of the FIGS. 9A-9C highlight the numbers of pixels summed along X axis on CCD when evaluating the momentum-dependent spectral response along Y axis. In general, the more pixels summed, the more severe the dispersion-induced mode broadening is. The inset to the right of FIG. 9C indicates reflectance spectra extracted at arbitrary k values in the momentum space from the graph of the left hand side of FIG. 9C.

Besides improving the resolution in wavelength and momentum (angle), the inventors also examine the influence of the number of pixels summed along the direction perpendicular to the visualized E-k cross-section (e.g., Δkₓ in X axis for a E-k cross-section cut along the Y axis). In common spectroscopy approaches using gratings, a slit must be applied as shown in the top inset of FIG. 9A. The slit width needs to balance the grating efficiency and resolution, and the optimal width in our setup turns out to be at least 20 pixels wide. This causes extra dispersion-induced mode broadening. Inventive technology allows summing of an arbitrary number of pixels, as illustrated in the top insets of FIGS. 9B and 9C. With more pixels summed (FIG. 9B), the signal-to-background ratio is higher, while the single pixel case (FIG. 9C) can provide the narrowest GMR feature, closer to the intrinsic GMR property. In the following, we discuss the E-k spectra with a few pixels summed and extraction of Q-factors from single-pixel data.

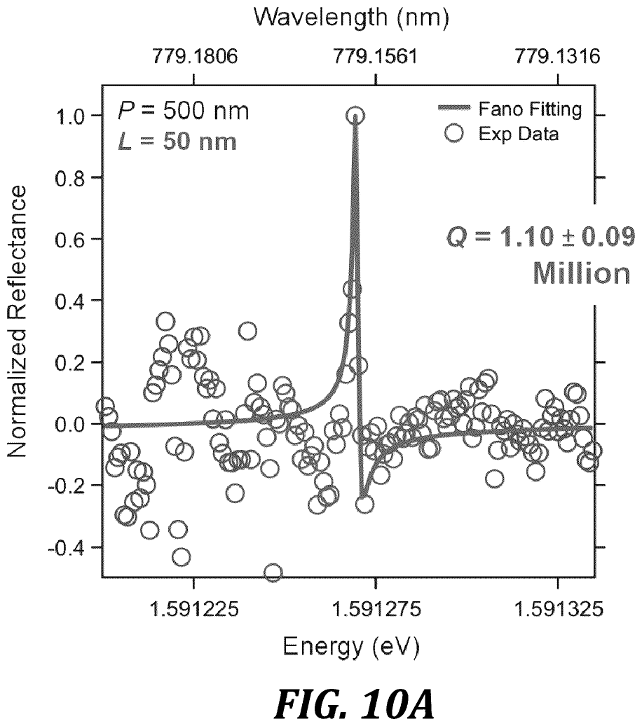

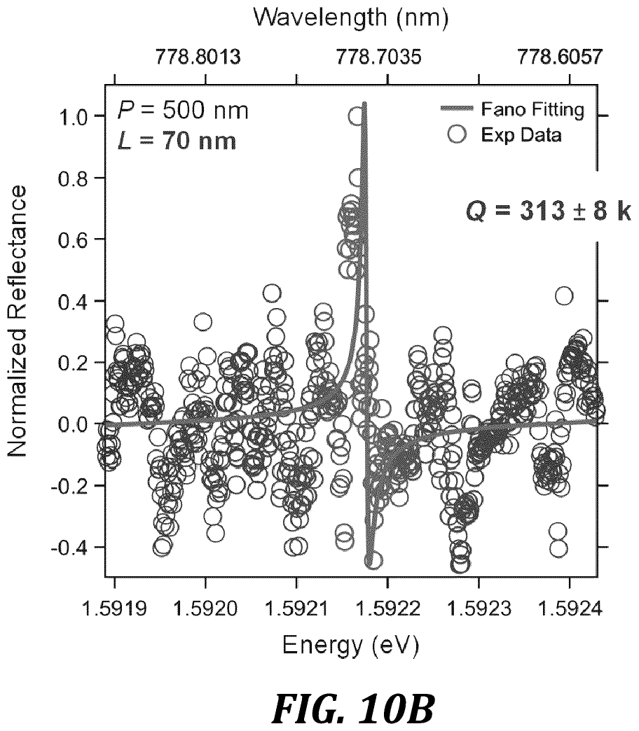

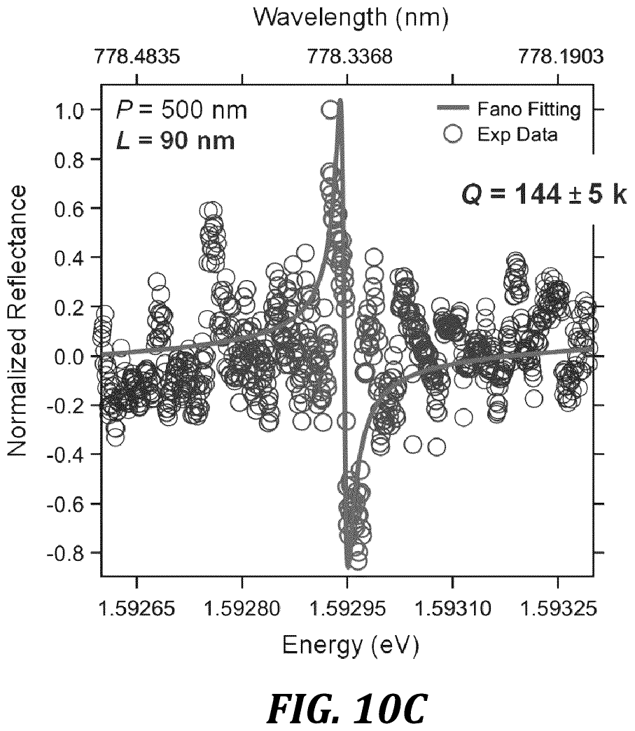

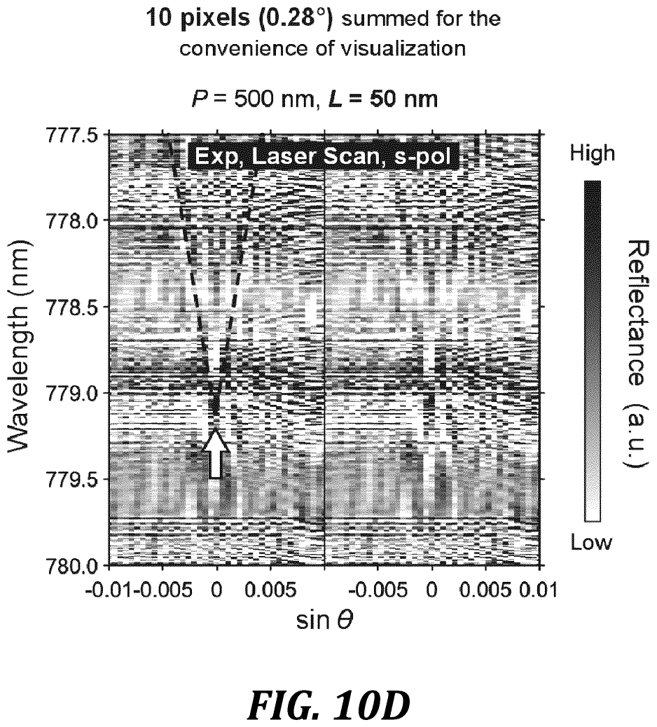

FIGS. 10A-10C illustrate several graphs of normalized reflectance spectra in accordance with embodiments of the present technology. FIG. 10D shows experimental results of reflectance signals at different wavelengths and light signal angles with respect to device surface normal in accordance with embodiments of the present technology. Collectively, these figures experimentally demonstrate a direct measurement million-Q GMR at visible and near-infrared wavelengths. With sufficient resolutions in E-k space and a clear GMR dispersion picture, we can extract high-wavelength-resolution 1D spectra at arbitrary k values and confidently identify the high-Q peaks originating from the GMR meta-resonator.

FIG. 10A shows reflectance spectra of the device with P=500 nm and L=50 nm at Γ point (normal incidence). The Fano fitting (red curve) reveals a Q factor of 1.10 million. The Γ-point data are extracted from extra-fine laser-scanning momentum-space-resolved reflectance spectroscopy with a wavelength resolution of ˜0.42 pm/pixel and an angle resolution of ˜0.0280/pixel. Relatedly, FIG. 10D shows the momentum-space-resolved spectra where the Γ-point data is extracted from. Note that a 0.28° range (10 pixels) of data are summed to broaden the ultranarrow mode linewidth for the convenience of visualization here in FIG. 10D, but only single-pixel data are used for Fano fittings. The same momentum-space-resolved spectra are plotted twice, one with the red dashed lines highlighting the dispersion of GMR. The arrow points to the Γ-point resonance. FIGS. 10B and 10C illustrate measurements that are analogous to those of FIG. 10A, but for the devices with L=70 nm in FIG. 10B and L=90 nm FIG. 10C. The fitted Q factors are 313 and 144 thousand respectively.

As illustrated in Table 1, our report of a million Q in the experiment is orders of magnitude higher than state-of-the-art demonstrations in visible-wavelength free space meta-optics¹⁶⁻²¹.

TABLE 1
Experimentally reported Q-factors in free-space optics at visible wavelengths.

| Source | Q | λ (nm) | Design/Structure | Device size (μm²) |
|---|---|---|---|---|
| Prior art | 8,000 | 750 | GMR/SiO₂ grating on SiN waveguide | 10,000 × 15,000 |
| Prior art | 391 | 860 | GMR/photoresist grating on HfO₂ waveguide | \ |
| Prior art | 32,000 | 490 | GMR/SiN photonic crystal slab | 600 × 600 |
| Prior art | 10,000 | 583 | Symmetry-protected BIC/SiN photonic crystal slab | 7,000 × 7,000 |
| Prior art | 2750 | 825 | Symmetry-protected BIC/GaAs metasurface | 60 × 108 |
| Prior art | 2750 | 717 | Resonance-trapped BIC/TiO₂ lattice | 500 × 500 |
| | | | on dielectric-covered mirror | |
| This work | 1,100,000 | 779 | GMR/patterned PMMA resist on SiN waveguide | 900 × 900 |

Specific elements of any foregoing embodiments can be combined or substituted for elements in other embodiments. Moreover, the inclusion of specific elements in at least some of these embodiments may be optional, wherein further embodiments may include one or more embodiments that specifically exclude one or more of these specific elements. Furthermore, while advantages associated with certain embodiments of the disclosure have been described in the context of these embodiments, other embodiments may also exhibit such advantages, and not all embodiments need necessarily exhibit such advantages to fall within the scope of the disclosure.

As used herein and unless otherwise indicated, the terms “a” and “an” are taken to mean “one”, “at least one” or “one or more”. Unless otherwise required by context, singular terms used herein shall include pluralities and plural terms shall include the singular.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “above,” and “below” and words of similar import, when used in this application, shall refer to this application as a whole and not to any particular portions of the application.

Unless otherwise indicated, all numbers expressing quantities of components, molecular weights, and so forth used in the specification and claims are to be understood as being modified in all instances by the term “about.” Accordingly, unless otherwise indicated to the contrary, the numerical parameters set forth in the specification and claims are approximations that may vary depending upon the desired properties sought to be obtained by the present invention. At the very least, and not as an attempt to limit the doctrine of equivalents to the scope of the claims, each numerical parameter should at least be construed in light of the number of reported significant digits and by applying ordinary rounding techniques. In the context of this disclosure, the term “about,” approximately” and similar means +/−5% of the stated value.

Notwithstanding that the numerical ranges and parameters setting forth the broad scope of the invention are approximations, the numerical values set forth in the specific examples are reported as precisely as possible. All numerical values, however, inherently contain a range necessarily resulting from the standard deviation found in their respective testing measurements.

All headings are for the convenience of the reader and should not be used to limit the meaning of the text that follows the heading, unless so specified.

All of the references cited herein are incorporated by reference. Aspects of the disclosure can be modified, if necessary, to employ the systems, functions, and concepts of the above references and application to provide yet further embodiments of the disclosure. These and other changes can be made to the disclosure in light of the detailed description.

It will be appreciated that, although specific embodiments of the invention have been described herein for purposes of illustration, various modifications may be made without deviating from the spirit and scope of the invention. Accordingly, the invention is not limited except as by the claims.

What is claimed is:

1. A free space optical resonator, comprising:
a low refractive index layer;
a high refractive index layer having a wide band gap; and
a low refractive index resist layer, wherein the high refractive index layer is disposed between the low refractive index layer and the resist layer,
wherein the low refractive index resist layer comprises a 2-D subwavelength periodic pattern of openings, wherein the low refractive index layer, the high refractive index layer and the low refractive index resist layer are arranged as a vertical stack, and wherein the optical resonator is lossless at visible wavelengths of light.

2. The free space optical resonator of claim 1, further comprising an active light emitting semiconductor layer.

3. The free space optical resonator of claim 2, wherein the active light emitting layer is configured between the low refractive index resist layer and the high refractive index layer.

4. The free space optical resonator of claim 3, wherein the active light emitting layer is configured to generate light that matches with characteristic wavelengths of operation of the free space optical resonator.

5. The free space optical resonator of claim 1, further comprising a silicon (Si) substrate layer configured to carry the vertical stack of layers.

6. The free space optical resonator of claim 1, wherein the low refractive index resist layer is a polymethyl methacrylate (PMMA) layer.

7. The free space optical resonator of claim 6, wherein the low refractive index layer is a silicon oxide (SiO₂) layer.

8. The free space optical resonator of claim 7, wherein the high refractive layer is silicon nitride (SiN) layer.

9. The free space optical resonator of claim 1, wherein the optical resonator is an etch-free optical resonator.

10. The free space optical resonator of claim 9, wherein the periodic pattern of openings is made at least in part by electron-beam lithography.

11. The free space optical resonator of claim 10, wherein the electron-beam lithography is performed over the low refractive index resist layer that is spin-coated and annealed.

12. The free space optical resonator of claim 1, wherein the periodic pattern of openings is defined by a patterning period P, wherein P is λ/(k_{GM}/k₀), where:
λ is an operation wavelength of light;
k_{GM} is a guided mode propagation constant determined by thicknesses and materials of each layer and varies at different operation wavelengths; and
k₀ is a free space wave vector.

13. The free space optical resonator of claim 12, wherein the periodic pattern of openings is further defined by a characteristic dimension L of an individual opening of the periodic pattern of openings.

14. The free space optical resonator of claim 13, wherein reducing the characteristic dimension L results in a higher Q.

15. The free space optical resonator of claim 13, wherein the characteristic dimension L is within a range of 50 nm to 90 nm.

16. The free space optical resonator of claim 15, wherein the patterning period P is within a range of 480 nm to 500 nm.

17. The free space optical resonator of claim 1, wherein a Q-factor of the optical resonator is greater than 1 million.

18. A method of processing light signals using the free space optical resonator of claim 1.

19. A method of manufacturing a free space optical resonator, the method comprising:
disposing a low refractive index layer;
disposing a high refractive index layer having a wide band gap over the low refractive index layer;
disposing a low refractive index resist layer over the high refractive index layer;
etch-free patterning the low refractive index resist layer in a 2-D subwavelength periodic pattern of openings,
wherein the optical resonator is lossless at visible wavelengths of light.

20. The method of claim 19, further comprising:
prior to disposing the low refractive index resist layer, forming an active light emitting layer over the high refractive index layer.

21. The method of claim 20, wherein the active light emitting layer is configured to generate light that matches with characteristic wavelengths of operation of the free space optical resonator.

22. The method of claim 19, further comprising disposing a silicon (Si) substrate layer, wherein the Si substrate layer is configured to carry the low refractive index layer.

23. The method of claim 19, wherein the low refractive index resist layer is a polymethyl methacrylate (PMMA) layer.

24. The method of claim 23, wherein the low refractive index layer is a silicon oxide (SiO₂) layer.

25. The method of claim 24, wherein the high refractive layer having a wide band gap is silicon nitride (SiN) layer.
